(19) United States
(12) Patent Application Publication
(10) Pub. No.: US 2026/0282434 A1
(43) Pub. Date: Sep. 17, 2026

(54) SEMICONDUCTOR DEVICE

(71) Applicants: KABUSHIKI KAISHA TOSHIBA, Kawasaki-shi (JP); TOSHIBA ELECTRONIC DEVICES & STORAGE CORPORATION, Kawasaki-shi (JP)

(72) Inventor: Kouta TOMITA, Nonoichi Ishikawa (JP)

(73) Assignees: KABUSHIKI KAISHA TOSHIBA, Kawasaki-shi (JP); TOSHIBA ELECTRONIC DEVICES & STORAGE CORPORATION, Kawasaki-shi (JP)

(21) Appl. No.: 19/311,025

(22) Filed: Aug. 27, 2025

(30) Foreign Application Priority Data
Mar. 17, 2025 (JP) 2025-042608

(51) Int. Cl. H10D 30/66; H10D 30/01; H10D 62/60; H10D 64/00; H10D 64/27

(52) U.S. Cl. CPC H10D 30/665; H10D 30/0297; H10D 30/668; H10D 64/112; H10D 64/117; H10D 64/516; H10D 62/60

(57) ABSTRACT

A semiconductor device according to an embodiment includes a first electrode, a second electrode, a semiconductor layer, first and second field plate (FP) electrode groups, a plurality of gate electrodes, a plurality of first and second conductive connection portions. The semiconductor layer includes a first semiconductor region of a first conductivity type, a second semiconductor region of a second conductivity type, and a third semiconductor region of the first conductivity type. The first and second FP electrode groups each include a plurality of FP electrodes arranged in the second direction. The second FP electrode group is adjacent to the first FP electrode group in the third direction. The plurality of first and second conductive connection portions electrically connect a plurality of gate electrodes surrounding each of the plurality of FP electrodes of the first and second FP electrode group, respectively.

### CROSS-REFERENCE TO RELATED APPLICATIONS

This application is based upon and claims the benefit of priority from the prior Japanese Patent Application No. 2025-042608, filed on Mar. 17, 2025; the entire contents of which are incorporated herein by reference.

### FIELD

Embodiments described herein relate generally to a semiconductor device.

### BACKGROUND

In a semiconductor device such as a metal oxide semiconductor field effect transistor (MOSFET), the switching speed of the semiconductor device can be improved by reducing gate-drain capacitance, which is parasitic capacitance between a gate electrode and a drain electrode.

On the other hand, in the related art, a semiconductor device including a plurality of field plate electrodes (FP electrodes) arranged in a dot shape has been known. In such a semiconductor device, in order to reduce the gate-drain capacitance, it is conceivable to provide a gate electrode in an insulating region in contact with each FP electrode. However, when the gate electrode is provided in the insulating region in contact with each FP electrode, a wiring structure for electrically connecting the gate electrodes may be complicated.

### BRIEF DESCRIPTION OF THE DRAWINGS

FIG. 1 is a plan view of a semiconductor device according to a first embodiment.

FIG. 2 is an enlarged view of a region R in FIG. 1.

FIG. 3 is a cross-sectional view of the semiconductor device according to the first embodiment, taken along line A-A in FIG. 2.

FIG. 4 is a cross-sectional view of the semiconductor device according to the first embodiment, taken along line B-B in FIG. 2.

FIG. 5 is a cross-sectional view of the semiconductor device according to the first embodiment, taken along line C-C in FIG. 2.

FIG. 6 is a plan view for explaining an example of a manufacturing process of the semiconductor device according to the first embodiment.

FIG. 7A is a cross-sectional view for explaining an example of the manufacturing process of the semiconductor device according to the first embodiment, taken along line A-A in FIG. 6.

FIG. 7B is a cross-sectional view for explaining an example of the manufacturing process of the semiconductor device according to the first embodiment, taken along line B-B in FIG. 6.

FIG. 7C is a cross-sectional view for explaining an example of the manufacturing process of the semiconductor device according to the first embodiment, taken along line C-C in FIG. 6.

FIG. 8 is a plan view for explaining an example of the manufacturing process of the semiconductor device according to the first embodiment, following FIG. 6.

FIG. 9A is a cross-sectional view for explaining an example of the manufacturing process of the semiconductor device according to the first embodiment, taken along line A-A in FIG. 8, following FIG. 7A.

FIG. 9B is a cross-sectional view for explaining an example of the manufacturing process of the semiconductor device according to the first embodiment, taken along line B-B in FIG. 8, following FIG. 7B.

FIG. 9C is a cross-sectional view for explaining an example of the manufacturing process of the semiconductor device according to the first embodiment, taken along line C-C in FIG. 8, following FIG. 7C.

FIG. 10 is a plan view for explaining an example of the manufacturing process of the semiconductor device according to the first embodiment, following FIG. 8.

FIG. 11A is a cross-sectional view for explaining an example of the manufacturing process of the semiconductor device according to the first embodiment, taken along line A-A in FIG. 10, following FIG. 9A.

FIG. 11B is a cross-sectional view for explaining an example of the manufacturing process of the semiconductor device according to the first embodiment, taken along line B-B in FIG. 10, following FIG. 9B.

FIG. 11C is a cross-sectional view for explaining an example of the manufacturing process of the semiconductor device according to the first embodiment, taken along line C-C in FIG. 10, following FIG. 9C.

FIG. 12 is a plan view for explaining an example of the manufacturing process of the semiconductor device according to the first embodiment, following FIG. 10.

FIG. 13A is a cross-sectional view for explaining an example of the manufacturing process of the semiconductor device according to the first embodiment, taken along line A-A in FIG. 12, following FIG. 11A.

FIG. 13B is a cross-sectional view for explaining an example of the manufacturing process of the semiconductor device according to the first embodiment, taken along line B-B in FIG. 12, following FIG. 11B.

FIG. 13C is a cross-sectional view for explaining an example of the manufacturing process of the semiconductor device according to the first embodiment, taken along line C-C in FIG. 12, following FIG. 11C.

FIG. 14 is a plan view for explaining an example of the manufacturing process of the semiconductor device according to the first embodiment, following FIG. 12.

FIG. 15A is a cross-sectional view for explaining an example of the manufacturing process of the semiconductor device according to the first embodiment, taken along line A-A in FIG. 14, following FIG. 13A.

FIG. 15B is a cross-sectional view for explaining an example of the manufacturing process of the semiconductor device according to the first embodiment, taken along line B-B in FIG. 14, following FIG. 13B.

FIG. 15C is a cross-sectional view for explaining an example of the manufacturing process of the semiconductor device according to the first embodiment, taken along line C-C in FIG. 14, following FIG. 13C.

FIG. 16 is a plan view for explaining an example of the manufacturing process of the semiconductor device according to the first embodiment, following FIG. 14.

FIG. 17A is a cross-sectional view for explaining an example of the manufacturing process of the semiconductor device according to the first embodiment, taken along line A-A in FIG. 16, following FIG. 15A.

FIG. 17B is a cross-sectional view for explaining an example of the manufacturing process of the semiconductor device according to the first embodiment, taken along line B-B in FIG. 16, following FIG. 15B.

FIG. 17C is a cross-sectional view for explaining an example of the manufacturing process of the semiconductor device according to the first embodiment, taken along line C-C in FIG. 16, following FIG. 15C.

FIG. 18 is a diagram corresponding to a cross-sectional view taken along line C-C in FIG. 2 in a semiconductor device according to Modification of the first embodiment.

FIG. 19 is a plan view of a semiconductor device according to a second embodiment.

FIG. 20 is a cross-sectional view of the semiconductor device according to the second embodiment, taken along line C-C in FIG. 19.

FIG. 21 is a plan view of a semiconductor device according to a third embodiment.

FIG. 22 is a plan view of a semiconductor device according to a fourth embodiment.

### DETAILED DESCRIPTION

A semiconductor device according to an embodiment includes a first electrode, a second electrode, a semiconductor layer, a first field plate electrode group, a second field plate electrode group, a plurality of gate electrodes, a plurality of first conductive connection portions, and a plurality of second conductive connection portions. The semiconductor layer is provided between the first electrode and the second electrode. The semiconductor layer includes a first semiconductor region of a first conductivity type, a second semiconductor region of a second conductivity type, and a third semiconductor region of the first conductivity type. The first semiconductor region is provided in the semiconductor layer, and electrically connected to the first electrode. The second semiconductor region is provided in the semiconductor layer and is located above the first semiconductor region. The third semiconductor region is provided in the semiconductor layer and is located above the second semiconductor region. The first field plate electrode group is provided in the first semiconductor region via a first insulating region, and includes a plurality of field plate electrodes arranged in a second direction orthogonal to a first direction from the first electrode toward the second electrode. The second field plate electrode group includes a plurality of field plate electrodes provided in the first semiconductor region via a second insulating region and arranged in the second direction. The second field plate electrode group is adjacent to the first field plate electrode group in a third direction orthogonal to the first direction and the second direction. The plurality of gate electrodes are provided in the first insulating region and the second insulating region so as to surround the plurality of field plate electrodes of the first field plate electrode group and each of the field plate electrodes of the plurality of field plate electrodes of the second field plate electrode group, respectively, and face the second semiconductor region. The plurality of first conductive connection portions are provided in the semiconductor layer via a third insulating region. The plurality of first conductive connection portions electrically connect the plurality of gate electrodes surrounding the plurality of field plate electrodes of the first field plate electrode group. The plurality of second conductive connection portions are provided in the semiconductor layer via a fourth insulating region. The plurality of second conductive connection portions electrically connect the plurality of gate electrodes surrounding the plurality of field plate electrodes of the second field plate electrode group.

Hereinafter, embodiments according to the present invention will be described with reference to the drawings. The embodiments do not limit the present invention. The drawings are schematic or conceptual, and the ratio of each portion and the like are not necessarily the same as actual ones. In the specification and the drawings, elements similar to those described above with respect to the previously described drawings are denoted by the same reference numerals, and the detailed description thereof is appropriately omitted.

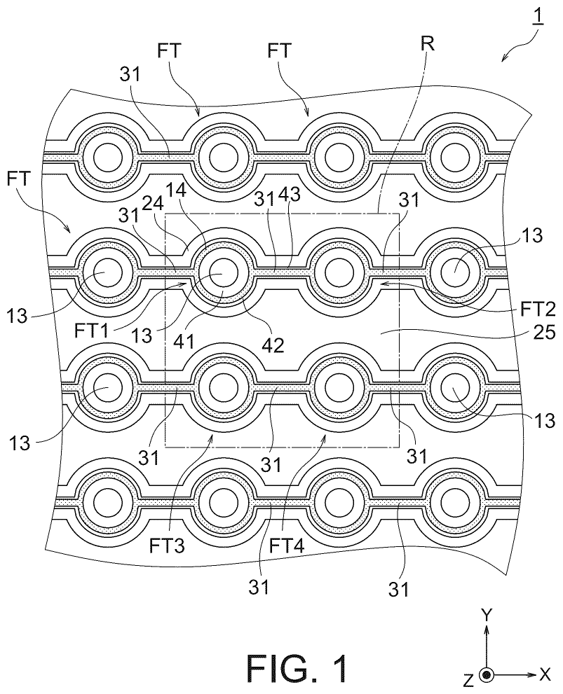

Further, for convenience of description, an XYZ orthogonal coordinate system is employed as illustrated in FIGS. 1 to 5 or the like. A Z-axis direction is a stacking direction (thickness direction) of the semiconductor device. In addition, in the Z-axis direction, a source electrode side is also referred to as “upper”, and a drain electrode side is also referred to as “lower”. However, this expression is for convenience and independent of the direction of gravity. The Z-axis direction is a first direction in the claims. An X-axis direction is a second direction in the claims. A Y-axis direction is a third direction in the claims.

In addition, in the following description, notations of n⁺, n, and n⁻, and p⁺, p, and p⁻ may be used to represent the relative level of impurity concentration in each conductivity type. That is, n⁺ indicates that an n-type impurity concentration is relatively higher than n, and n⁻ indicates that the n-type impurity concentration is relatively lower than n. In addition, p⁺ indicates that a p-type impurity concentration is relatively higher than p, and p⁻ indicates that the p-type impurity concentration is relatively lower than p. When both the p-type impurity and the n-type impurity are contained in each region, these notations represent the relative level of the net impurity concentration after the impurities have been compensated for. The n type, n⁺ type, and n⁻ type are examples of a first conductivity type in the claims. The p type, p⁺ type, and p⁻ type are examples of a second conductivity type in the claims. Note that in the following description, the n-type and the p-type may be reversed. That is, the first conductivity type may be the p-type.

In addition, the impurity concentration of the semiconductor region can be measured by, for example, secondary ion mass spectrometry (SIMS). In addition, the relative level of the impurity concentration can also be determined from the level of a carrier concentration obtained by, for example, scanning capacitance microscopy (SCM).

In addition, a dimension such as the thickness of a field plate insulating film can be measured by, for example, analysis of a surface and/or a cross section by a transmission electron microscope (TEM), an energy dispersive X-ray spectroscopy (EDX), or a scanning electron microscope (SEM).

Note that terms such as “identical”, “same”, and “equal”, dimensions, values of physical characteristics, and the like, which specify shapes, geometric conditions, physical characteristics, and the degrees thereof, used in the present specification, are interpreted including a range in which similar functions can be expected, without being bound by a strict meaning.

### First Embodiment

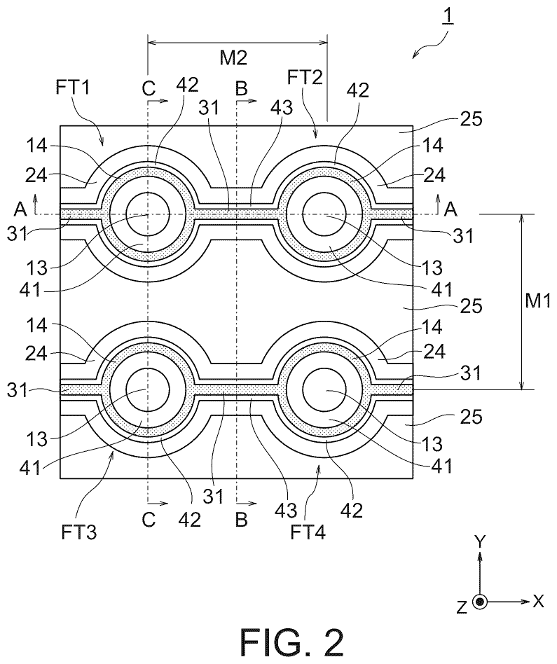

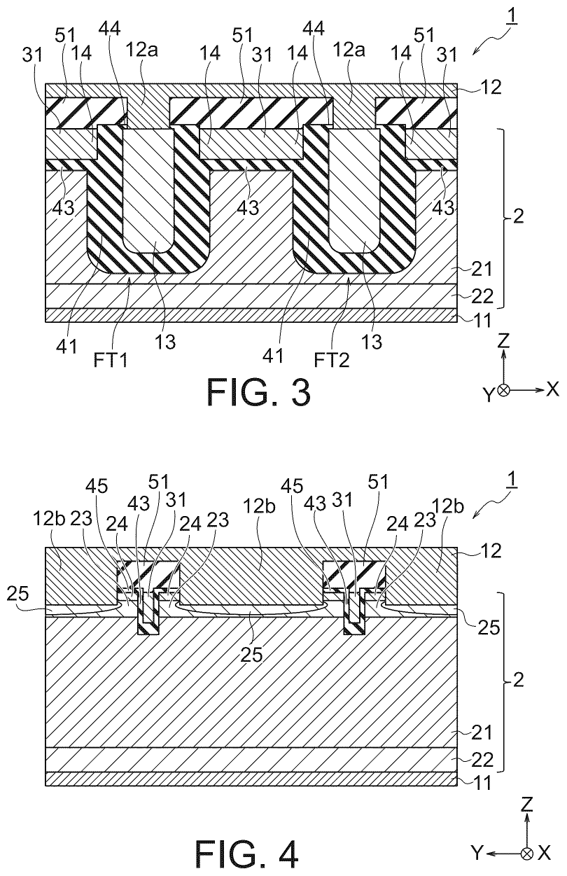

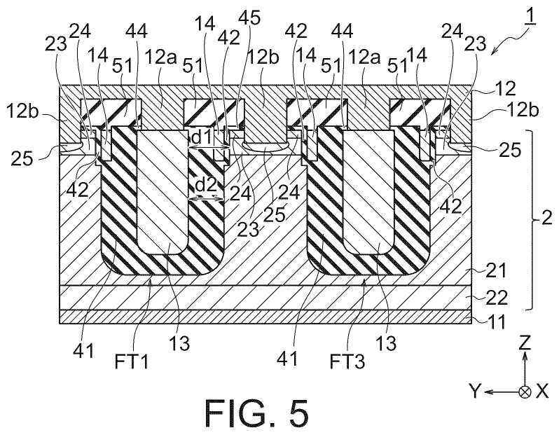

A semiconductor device 1 according to a first embodiment will be described with reference to FIGS. 1 to 5. FIG. 1 is a plan view of a semiconductor device 1 according to the first embodiment. FIG. 2 is an enlarged view of a region R in FIG. 1. FIG. 3 is a cross-sectional view of the semiconductor device 1 according to the first embodiment, taken along line A-A in FIG. 2. FIG. 4 is a cross-sectional view of the semiconductor device 1 according to the first embodiment, taken along line B-B in FIG. 2. FIG. 5 is a cross-sectional view of the semiconductor device 1 according to the first embodiment, taken along line C-C in FIG. 2. In FIGS. 1 and 2, a source electrode 12 (including a contact portion 12a and a contact portion 12b), an insulating region 44, an insulating region 45, and an insulating region 51 are omitted.

The semiconductor device 1 is, for example, a vertical MOSFET. The semiconductor device 1 may be a vertical transistor such as an insulated gate bipolar transistor (IGBT).

First, a planar structure of the semiconductor device 1 according to the present embodiment will be described. In the plane illustrated in FIG. 1, the semiconductor device 1 is provided with a plurality of field plate electrodes (FP electrodes) 13, a gate electrode 14, a source region 24, a high-concentration region 25, a conductive connection portion 31, an insulating region 41, an insulating region 42, and an insulating region 43.

The plurality of FP electrodes 13 are arranged side by side in a dot shape. In the present embodiment, the FP electrodes 13 are arranged at predetermined intervals along the X-axis direction and the Y-axis direction. The insulating region 41 is provided around each of the FP electrodes 13. The FP electrodes 13 and the insulating regions 41 are provided in field plate trenches (FP trenches) FT arranged in dots in the semiconductor layer 2. That is, in the semiconductor device 1, a plurality of FP trenches FT are formed so as to be arranged at predetermined intervals, and the FP electrode 13 and the insulating region 41 are formed in each FP trench FT.

In the following description, the FP trenches FT in the region R illustrated in FIG. 1 are referred to as an FP trench FT1, an FP trench FT2, an FP trench FT3, and an FP trench FT4, respectively. Here, the FP electrode 13 in the FP trench FT1 and the FP electrode 13 in the FP trench FT2 are adjacent to each other in the X-axis direction. In addition, the FP electrode 13 in the FP trench FT3 and the FP electrode 13 in the FP trench FT4 are adjacent to each other along the X-axis direction.

The plurality of FP electrodes 13 arranged in the X-axis direction are referred to as a field plate electrode group (FP electrode group). That is, each FP electrode group includes the plurality of FP electrodes 13 arranged in the X-axis direction. Each FP electrode group is provided side by side in the Y-axis direction. Note that the number of FP electrode groups included in the semiconductor device 1 is not limited to the example of FIG. 1, and may be any number of two or more. The number of FP electrodes 13 included in each FP electrode group may be any number of 2 or more.

The FP electrodes 13 in the FP trenches FT1 and FT2 and other FP electrodes 13 arranged with the FP electrodes 13 in the X-axis direction are referred to as a first field plate electrode group (first FP electrode group). Similarly, the FP electrodes 13 in the FP trenches FT3 and FT4 and other FP electrodes 13 arranged with the FP electrodes 13 in the X-axis direction are referred to as a second field plate electrode group (second FP electrode group). That is, each of the first FP electrode group and the second FP electrode group includes the plurality of FP electrodes 13 arranged in the X-axis direction. The second FP electrode group is adjacent to the first FP electrode group in the Y-axis direction.

In the present embodiment, the FP electrodes 13 provided in the semiconductor device 1 are arranged in a rectangular shape. That is, the FP electrodes 13 of the first FP electrode group and the FP electrodes 13 of the second FP electrode group are arranged along the Y-axis direction. For example, the FP trench FT1 and the FP trench FT3 are adjacent to each other along the Y-axis direction. Also, the FP trench FT2 and the FP trench FT4 are adjacent to each other along the Y-axis direction.

Next, the planar structure of the semiconductor device 1 will be described in more detail with reference to FIG. 2. As illustrated in FIG. 2, the FP electrode groups are arranged at predetermined intervals along the Y-axis direction. In the example of FIG. 2, a distance between the center of each FP electrode 13 of the first FP electrode group and the center of each FP electrode 13 of the second FP electrode group in the Y-axis direction is a distance M1. The FP electrodes 13 included in each FP electrode group are arranged at predetermined intervals along the X-axis direction. In the example of FIG. 2, the distance between the centers of the plurality of FP electrodes 13 of the first FP electrode group is a distance M2. In the present embodiment, the distance M2 is equal to the distance M1. In other words, the centers of the FP electrodes 13 in the FP trenches FT1 to FT4 are located at vertices of a square in the XY plane. Note that the distance M2 may be different from the distance M1. That is, the distance M2 may be longer or shorter than the distance M1.

The gate electrode 14 is provided so as to surround the FP electrode 13 in each FP trench FT via the insulating region 41. More specifically, the gate electrode 14 surrounds each FP electrode 13 of the plurality of FP electrodes 13 of the first FP electrode group and the plurality of FP electrodes 13 of the second FP electrode group. Note that the expression of surrounding the FP electrode 13 may include a case where a part of the gate electrode 14 is missing. An example of such a case includes a case where the gate electrode 14 surrounding the FP electrode 13 in the FP trench FT1 is cut at an upper portion (for example, one location on line C-C) of the FP electrode 13 in the FP trench FT1 in FIG. 2. In the following description, the gate electrode 14 and the like surrounding the FP electrode 13 in the FP trench FT1 are also referred to as “the gate electrode 14 of the FP trench FT1” and the like. The insulating region 42 is provided between the gate electrode 14 and the source region 24.

The conductive connection portion 31 is provided so as to electrically connect the gate electrodes 14 adjacent to each other in the X-axis direction. Some of the conductive connection portions 31 electrically connect the plurality of gate electrodes 14 surrounding each of the plurality of FP electrodes 13 of the first FP electrode group. These some of the conductive connection portions 31 are examples of the first conductive connection portion in the claims. That is, the conductive connection portion 31 as the first conductive connection portion electrically connects the plurality of gate electrodes 14 surrounding each of the FP electrodes 13 adjacent to each other in the X-axis direction in the first FP electrode group. For example, the conductive connection portion 31 located between the FP trench FT1 and the FP trench FT2 electrically connects the gate electrode 14 of the FP trench FT1 and the gate electrode 14 of the FP trench FT2. As another example, in FIG. 2, the conductive connection portion 31 located on the left side of the FP trench FT1 electrically connects the gate electrode 14 of the FP trench FT1 and the gate electrode 14 of the FP trench FT located on the left side of the FP trench FT1. In this manner, the gate electrodes 14 surrounding each of the respective FP electrodes 13 of the first FP electrode group are electrically connected to each other by the conductive connection portions 31. These gate electrodes 14 are electrically connected to a gate pad (not illustrated) in the termination region of the semiconductor device 1, for example.

In addition, some other conductive connection portions 31 among the conductive connection portions 31 electrically connect the plurality of gate electrodes 14 surrounding each of the plurality of FP electrodes 13 of the second FP electrode group. These some other conductive connection portions 31 are examples of the second conductive connection portion in the claims. That is, the conductive connection portion 31 as the second conductive connection portion electrically connects the plurality of gate electrodes 14 surrounding each of the FP electrodes 13 adjacent to each other in the X-axis direction in the second FP electrode group. For example, the conductive connection portion 31 located between the FP trench FT3 and the FP trench FT4 electrically connects the gate electrode 14 of the FP trench FT3 and the gate electrode 14 of the FP trench FT4. As another example, in FIG. 2, the conductive connection portion 31 located on the left side of the FP trench FT3 electrically connects the gate electrode 14 of the FP trench FT3 and the gate electrode 14 of the FP trench FT located on the left side of the FP trench FT3. In this manner, the gate electrodes 14 surrounding each of the respective FP electrodes 13 of the second FP electrode group are electrically connected to each other by the conductive connection portions 31. These gate electrodes 14 are electrically connected to a gate pad (not illustrated) in the termination region of the semiconductor device 1, for example.

The insulating region 43 is provided between the conductive connection portion 31 and the source region 24. The insulating region 43 connects the insulating regions 41 provided in the FP trenches FT adjacent to each other in the X-axis direction. For example, the insulating region 43 connects the insulating region 41 in the FP trench FT1 and the insulating region 41 in the FP trench FT2. Further, the insulating region 43 connects the insulating region 41 in the FP trench FT3 and the insulating region 41 in the FP trench FT4. The insulating region 43 is an example of the third insulating region and the fourth insulating region in the claims. More specifically, the insulating region 43 connecting the insulating region 41 in the FP trench FT1 and the insulating region 41 in the FP trench FT2 is an example of the third insulating region. In addition, the insulating region 43 connecting the insulating region 41 in the FP trench FT3 and the insulating region 41 in the FP trench FT4 is an example of the fourth insulating region. In the plane illustrated in FIG. 2, the high-concentration region 25 is located between one source region 24 and the other source region 24.

Next, a cross-sectional structure of the semiconductor device 1 according to the present embodiment will be specifically described with reference to FIGS. 3 to 5. As illustrated in FIGS. 3 to 5, the semiconductor device 1 according to the present embodiment includes a semiconductor layer 2, a drain electrode 11, a source electrode 12, an insulating region 44, an insulating region 45, and an insulating region 51.

The semiconductor layer 2 is provided between the drain electrode 11 and the source electrode 12. The semiconductor layer 2 includes a lower surface on which the drain electrode 11 is provided and an upper surface opposite to the lower surface. On the upper surface of the semiconductor layer 2, the source electrode 12 is provided via the insulating region 44, the insulating region 45, and the insulating region 51. Various semiconductor regions described later and the like are provided in the semiconductor layer 2.

The semiconductor layer 2 may be an epitaxial layer, a semiconductor substrate, or a semiconductor substrate and an epitaxial layer disposed on the semiconductor substrate. In the present embodiment, the semiconductor layer 2 is silicon (Si). In this case, for example, arsenic (As), phosphorus (P), or antimony (Sb) is used as the n-type impurity, and for example, boron (B) is used as the p-type impurity. Note that the semiconductor layer 2 may be made of a compound semiconductor such as silicon carbide (SiC) or gallium nitride (GaN).

The drain electrode 11 functions as a drain electrode of the MOSFET. The drain electrode 11 is in ohmic contact with a drain region 22, for example. The drain electrode 11 contains, for example, at least one of copper (Cu), titanium (Ti), tungsten (W), and aluminum (Al). The drain electrode 11 is an example of the first electrode in the claims.

The source electrode 12 functions as a source electrode of the MOSFET. The source electrode 12 contains, for example, at least one of copper (Cu), titanium (Ti), tungsten (W), and aluminum (Al). The source electrode 12 is an example of a second electrode in the claims.

As illustrated in FIGS. 3 to 5, in the present embodiment, the source electrode 12 includes a contact portion 12a and a contact portion 12b protruding downward. As illustrated in FIGS. 3 and 5, the contact portion 12a penetrates the insulating region 51 and the insulating region 44, and reaches the FP electrode 13. The source electrode 12 is electrically connected to the FP electrode 13 via the contact portion 12a. The insulating region 51 is, for example, an interlayer insulating film provided on the upper surface of the semiconductor layer 2 and contains silicon oxide or silicon nitride. The insulating region 44 is, for example, a silicon oxide film provided on the FP electrode 13.

In addition, as illustrated in FIGS. 4 and 5, the contact portion 12b penetrates the insulating region 51, the insulating region 45, and the source region 24 and reaches the high-concentration region 25. The source electrode 12 is in ohmic contact with, for example, the source region 24 and the high-concentration region 25 via the contact portion 12b. The insulating region 45 is, for example, a silicon oxide film provided on the source region 24.

Next, a configuration in the semiconductor layer 2 will be described. As illustrated in FIGS. 3 to 5, the FP electrode 13, the gate electrode 14, a drift region 21, the drain region 22, a base region 23, the source region 24, the high-concentration region 25, the conductive connection portion 31, the insulating region 41, the insulating region 42, and the insulating region 43 are provided in the semiconductor layer 2.

The FP electrode 13 is provided in a columnar shape in the drift region 21 via the insulating region 41. The FP electrode 13 is electrically insulated from the semiconductor layer 2 and the gate electrode 14 by the insulating region 41. The FP electrode 13 is electrically connected to the source electrode 12 via the contact portion 12a. The FP electrode 13 is made of, for example, polysilicon containing p-type or n-type impurities. By providing the FP electrode 13, when the semiconductor device 1 is in an off state, a depletion layer extends from the insulating region 41 where the FP electrode 13 is disposed to the drift region 21 around the insulating region 41 by a reverse voltage applied between the drain electrode 11 and the source electrode 12. Since this depletion layer is connected to an adjacent depletion layer extending from the insulating region 41 in which the FP electrode 13 is disposed, the withstand voltage of the semiconductor device 1 can be improved.

The insulating region 41 is provided in the drift region 21, and the FP electrode 13 is disposed therein. In the present embodiment, the insulating region 41 is provided on the inner wall of the FP trench FT (for example, the FP trenches FT1 to FT4), that is, below and on the side of the FP electrode 13. Note that the insulating region 41 contains, for example, a silicon oxide or a silicon nitride. The insulating region 41 is an example of the first insulating region and the second insulating region in the claims.

The gate electrode 14 functions as a gate electrode of the MOSFET. The gate electrode 14 is provided in the insulating region 41 in contact with the FP electrode 13, and faces the base region 23 with the insulating region 42 interposed therebetween. The gate electrode 14 is electrically insulated from the semiconductor layer 2 by the insulating region 42. In the present embodiment, the gate electrode 14 is located on the side of the FP electrode 13. As illustrated in FIGS. 4 and 5, an upper end of the gate electrode 14 is located closer to the source electrode 12 than an upper end of the base region 23. A lower end of the gate electrode 14 is located closer to the drain electrode 11 than a lower end of the base region 23, and is located closer to the source electrode 12 than a lower end of the FP electrode 13. The gate electrode 14 is made of, for example, polysilicon containing p-type or n-type impurities. When a voltage is applied to the gate electrode 14, a channel is formed in the base region 23 in a portion facing the gate electrode 14, and carriers (electrons in the present embodiment) flow between the drift region 21 (drain region 22) and the source region 24. As a result, the MOSFET is brought into an on-state.

The insulating region 42, for example, faces the base region 23 and the source region 24, and electrically insulates the gate electrode 14 from the semiconductor layer 2. The insulating region 42 is provided on the side of the gate electrode 14. Note that the insulating region 42 may be treated as a part of the insulating region 41. Note that the insulating region 42 contains, for example, a silicon oxide or a silicon nitride.

As illustrated in FIG. 5, in the present embodiment, for at least one FP trench FT, the outer periphery of the insulating region 42 is farther from the center of the FP electrode 13 than the outer periphery of the insulating region 41. For example, in the FP trench FT1, the outer periphery of the insulating region 42 is farther from the center of the FP electrode 13 than the outer periphery of the insulating region 41. In other words, for the FP trench FT1, a first distance d1 between the FP electrode 13 and the semiconductor layer 2 at the first height at which the gate electrode 14 is provided is longer than a second distance d2 between the FP electrode 13 and the semiconductor layer 2 at the second height at which the gate electrode 14 is not provided. In the present embodiment, the first distance d1 is a distance from the side end of the FP electrode 13 to the side end of the base region 23, and the second distance d2 is a distance from the side end of the FP electrode 13 to the side end of the drift region 21. As described above, in the present embodiment, in at least one FP electrode 13, the distance between the FP electrode 13 and the semiconductor layer 2 at the height at which the gate electrode 14 surrounding the FP electrode 13 is provided is longer than the distance between the FP electrode 13 and the semiconductor layer 2 at the height at which the gate electrode 14 is not provided. As a result, it is possible to suppress the thickness of the insulating region 42 from becoming uneven in a manufacturing process of the semiconductor device 1 described later.

As illustrated in FIGS. 3 to 5, the drift region 21 functions as a drift region of the MOSFET. The drift region 21 is disposed on the drain region 22 (above the drain electrode 11). The drift region 21 is, for example, an n⁻ type semiconductor region. The n-type impurity concentration of the drift region 21 is, for example, 1×10¹⁵ cm⁻³ or more and 2×10¹⁶ cm⁻³ or less.

The drain region 22 functions as a drain region of the MOSFET. The drain region 22 is located on the drain electrode 11 and is disposed between the drift region 21 and the drain electrode 11. The drain region 22 is in contact with the drain electrode 11 and is electrically connected to the drain electrode 11. The drain region 22 is, for example, an n⁺-type semiconductor region. An n-type impurity concentration of the drain region 22 is, for example, 1×10¹⁸ cm⁻³ or more and 1×10²¹ cm⁻³ or less.

The drift region 21 and the drain region 22 are examples of a first semiconductor region in the claims. Note that the drain region 22 may not be provided. In this case, the drift region 21 is directly provided on the drain electrode 11, and the drain electrode 11 is electrically connected to the drift region 21. Alternatively, the drift region 21 may not be provided. In this case, for example, the drain region 22 is also provided at the position of the drift region 21.

As illustrated in FIGS. 4 and 5, the base region 23 functions as a base region of the MOSFET. The base region 23 is located above the drift region 21. The base region 23 is, for example, a p-type semiconductor region. The p-type impurity concentration of the base region 23 is, for example, 1×10¹⁶ cm⁻³ or more and 1×10²⁰ cm⁻³ or less. The base region 23 is an example of a second semiconductor region in the claims.

The source region 24 functions as a source region of the MOSFET. The source region 24 is located above the base region 23. The source region 24 is in contact with the contact portion 12b and is electrically connected to the source electrode 12 via the contact portion 12b. The source region 24 is, for example, an n⁺-type semiconductor region. The n-type impurity concentration of the source region 24 is, for example, 1×10¹⁸ cm⁻³ or more and 1×10²² cm⁻³ or less. The source region 24 is an example of a third semiconductor region in the claims.

The high-concentration region 25 is provided so as to wrap the lower end of the contact portion 12b in the base region 23. The high-concentration region 25 is in contact with the contact portion 12b and is electrically connected to the source electrode 12 via the contact portion 12b. The high-concentration region 25 is, for example, a p⁺-type semiconductor region. That is, the p-type impurity concentration of the high-concentration region 25 is higher than the p-type impurity concentration of the base region 23. The p-type impurity concentration of the high-concentration region 25 is, for example, 1×10¹⁸ cm⁻³ or more and 1×10²¹ cm⁻³ or less. By providing the high-concentration region 25, holes remaining in the base region 23 are easily discharged to the source electrode 12 via the contact portion 12b. Thus, the avalanche withstand capability of the semiconductor device 1 can be improved.

As illustrated in FIGS. 3 and 4, the conductive connection portion 31 is provided in the semiconductor layer 2 via the insulating region 43. As illustrated in FIG. 3, the conductive connection portion 31 extends in the X-axis direction, and electrically connects the gate electrodes 14 surrounding each of the FP electrodes 13 adjacent to each other in the X-axis direction. In the example of FIG. 3, the conductive connection portion 31 electrically connects the gate electrode 14 of the FP trench FT1 and the gate electrode 14 of the FP trench FT2. In other words, the gate electrodes 14 surrounding each of the FP electrodes 13 adjacent to each other in the X-axis direction are electrically connected to each other by the conductive connection portions 31 provided in the trenches connecting the FP trenches FT adjacent to each other in the X-axis direction.

In the present embodiment, as illustrated in FIG. 4, the conductive connection portion 31 is provided to face a part of the source region 24, the base region 23, and a part of the drift region 21 via the insulating region 43. That is, the conductive connection portion 31 faces the base region 23 via the insulating region 43. As a result, a channel region is formed not only in the base region 23 in the portion facing the gate electrode 14 but also in the base region 23 in the portion facing the conductive connection portion 31, and the on-resistance of the semiconductor device 1, more specifically, the channel resistance can be reduced. Note that the conductive connection portion 31 is provided simply for electrically connecting the gate electrodes 14, and may not function as a gate electrode itself. For example, at least one conductive connection portion 31 may not be provided in the base region 23 but may be provided in another semiconductor region in the semiconductor layer 2. For example, at least one conductive connection portion 31 may be provided in the drift region 21 via an insulating region.

In the present embodiment, the upper end of at least one conductive connection portion 31 of the plurality of conductive connection portions 31 is located in the source region 24 in the Z-axis direction, and the lower end of the at least one conductive connection portion 31 is located in the drift region 21 in the Z-axis direction. In other words, the at least one conductive connection portion 31 faces the base region 23 from the upper end to the lower end of the base region 23. As a result, in the base region 23 facing the at least one conductive connection portion 31, a channel region is formed from the upper end to the lower end of the base region 23. Therefore, the on-resistance of the semiconductor device 1 can be further reduced.

As illustrated in FIG. 3, in the present embodiment, the upper ends of the plurality of conductive connection portions 31 are located at the same height in the Z-axis direction as the upper ends of the gate electrodes 14, and the lower ends of the plurality of conductive connection portions 31 are located at the same height in the Z-axis direction as the lower ends of the gate electrodes 14. That is, the upper ends of the plurality of conductive connection portions 31 and the upper ends of the gate electrodes 14 have the same position (Z coordinate) in the Z-axis direction, and the lower ends of the plurality of conductive connection portions 31 and the lower ends of the gate electrodes 14 have the same position in the Z-axis direction. Thus, the gate electrode 14 and the conductive connection portion 31 can be collectively formed in the manufacturing process of the semiconductor device 1. Note that the upper end of the at least one conductive connection portion 31 may be located at a height different from the upper end of the gate electrode 14. In addition, the lower end of the at least one conductive connection portion 31 may be located at a height different from the lower end of the gate electrode 14.

The insulating region 43 electrically insulates the conductive connection portion 31 from the semiconductor layer 2. The insulating region 43 is provided on the inner wall of the trench in which the conductive connection portion 31 is provided. As illustrated in FIG. 4, in the present embodiment, the insulating region 43 is provided below and on the side of the conductive connection portion 31. In the present embodiment, the insulating region 43 is in contact with the base region 23 and the source region 24. Note that the insulating region 43 contains, for example, a silicon oxide or a silicon nitride.

As described above, the semiconductor device 1 according to the present embodiment includes the drain electrode 11, the source electrode 12, the semiconductor layer 2, the first FP electrode group, the second FP electrode group, the plurality of gate electrodes 14, and the plurality of conductive connection portions 31. The semiconductor layer 2 is provided between the drain electrode 11 and the source electrode 12. The semiconductor layer 2 includes the drift region 21 of the first conductivity type, the drain region 22 of the first conductivity type, the base region 23 of the second conductivity type, and the source region 24 of the first conductivity type. The drain region 22 is provided in the semiconductor layer 2 and is electrically connected to the drain electrode 11. The drift region 21 is provided in the semiconductor layer 2 and is located on the drain region 22. The base region 23 is provided in the semiconductor layer 2 and is located on the drift region 21. The source region 24 is provided in the semiconductor layer 2 and is located above the base region 23. The first FP electrode group includes a plurality of FP electrodes 13 arranged in the X-axis direction. Each of the plurality of the FP electrode 13 of the first FP electrode group is provided in the drift region 21 via the insulating region 41. The second FP electrode group includes a plurality of FP electrodes 13 arranged in the X-axis direction. Each of the plurality of the FP electrode 13 of the second FP electrode group is provided in the drift region 21 via the insulating region 41. The second FP electrode group is adjacent to the first FP electrode group in the Y-axis direction. The plurality of gate electrodes 14 are provided in the insulating region 41 so as to surround each FP electrode 13 of the plurality of FP electrodes 13 of the first FP electrode group and the plurality of FP electrodes 13 of the second FP electrode group, and face the base region 23. The plurality of conductive connection portions 31 is provided in the semiconductor layer 2 via the insulating region 43. Some conductive connection portions 31 among the plurality of conductive connection portions 31 electrically connect the plurality of gate electrodes 14 surrounding each of the plurality of FP electrodes 13 of the first FP electrode group. Some other conductive connection portions 31 among the plurality of conductive connection portions 31 electrically connect the plurality of gate electrodes 14 surrounding each of the plurality of FP electrodes 13 of the second FP electrode group.

In the semiconductor device 1 according to the present embodiment, in the semiconductor device 1 including the FP electrodes 13 arranged in a dot shape in the semiconductor layer 2 via the insulating region 41 and the gate electrodes 14 provided so as to surround the FP electrodes 13 in the insulating region 41, the gate electrodes 14 are electrically connected by the conductive connection portions 31 provided in the semiconductor layer 2. As a result, for example, a wiring structure for electrically connecting the gate electrodes 14 can be simplified. For example, it is possible to omit provision of wiring including a contact plug above the semiconductor layer 2 in order to electrically connect the gate electrodes 14. Therefore, the manufacturing cost of the semiconductor device 1 can be reduced. In addition, miniaturization of the semiconductor device 1 can be further facilitated, and a yield in manufacturing of the semiconductor device 1 can be improved.

In the semiconductor device 1 according to the present embodiment, the gate electrode 14 is provided so as to surround the FP electrode 13 in the same FP trench FT as the FP electrode 13. As a result, the gate-drain capacitance that is the parasitic capacitance between the gate electrode 14 and the drain electrode 11 can be reduced as compared with a case where the gate electrode 14 is provided in a trench different from the FP electrode 13. Therefore, for example, the switching speed of the semiconductor device 1 can be improved, and the switching loss can be reduced.

In addition, according to the semiconductor device 1 according to the present embodiment, the conductive connection portion 31 is provided to face a part of the source region 24, the base region 23, and a part of the drift region 21. As a result, since a channel is also formed in the base region 23 around the conductive connection portion 31, the on-resistance of the semiconductor device 1, more specifically, the channel resistance can be reduced. That is, according to the present embodiment, the on-resistance can be reduced in addition to the effect of reducing the gate-drain capacitance described above. Therefore, according to the present embodiment, the trade-off between the gate-drain capacitance and the on-resistance in the semiconductor device 1 can be improved.

### Method for Manufacturing Semiconductor Device 1

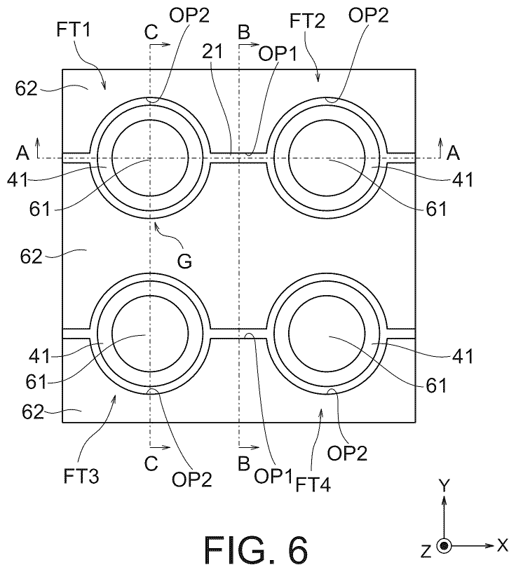

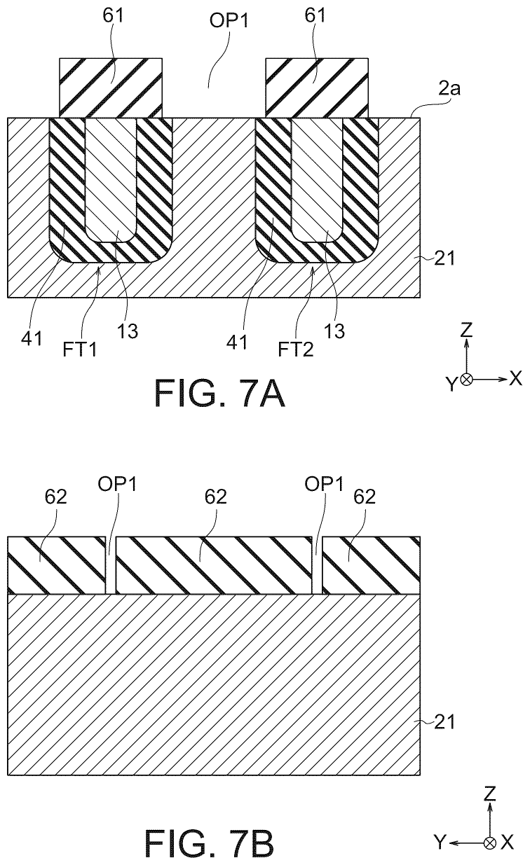

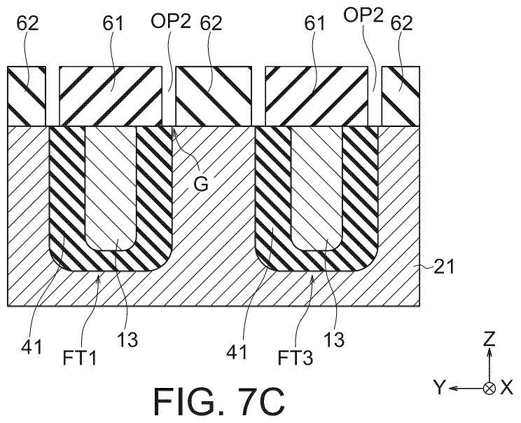

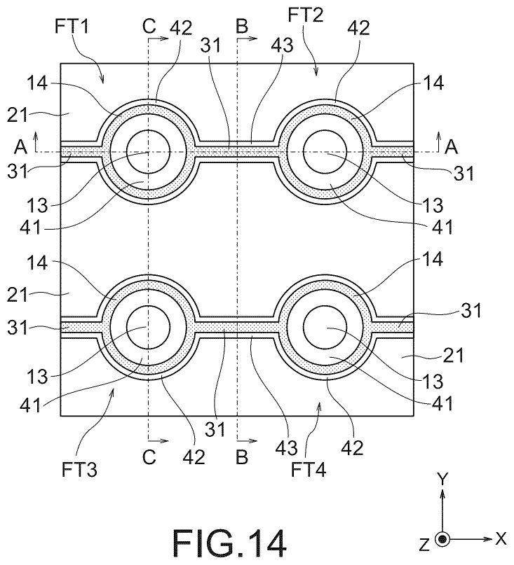

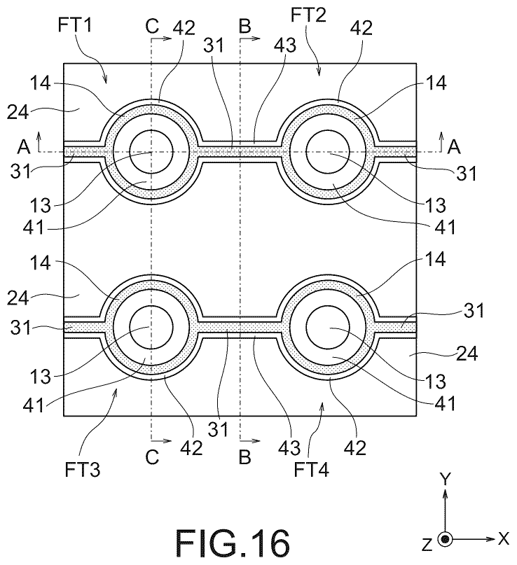

Next, an example of a method for manufacturing the semiconductor device 1 according to the present embodiment will be described with reference to FIGS. 6 to 17C. FIGS. 6, 8, 10, 12, 14, and 16 are plan views for explaining an example of the manufacturing process of the semiconductor device 1 according to the first embodiment, and are enlarged views of a region corresponding to a region R in FIG. 1. FIGS. 7A, 9A, 11A, 13A, 15A, and 17A are cross-sectional views taken along line A-A of FIGS. 6, 8, 10, 12, 14, and 16, respectively, for explaining an example of the manufacturing process of the semiconductor device 1 according to the first embodiment. FIGS. 7B, 9B, 11B, 13B, 15B, and 17B are cross-sectional views taken along line B-B of FIGS. 6, 8, 10, 12, 14, and 16, respectively, for explaining an example of the manufacturing process of the semiconductor device 1 according to the first embodiment. FIGS. 7C, 9C, 11C, 13C, 15C, and 17C are cross-sectional views taken along line C-C of FIGS. 6, 8, 10, 12, 14, and 16, respectively, for explaining an example of the manufacturing process of the semiconductor device 1 according to the first embodiment. In FIG. 14, the insulating region 44 and the insulating region 45 are omitted. In FIG. 16, the insulating region 44, the insulating region 45, and the insulating region 51 are omitted.

First, the semiconductor layers illustrated in FIGS. 6 and 7A to 7C are prepared. In the semiconductor layer, the drift region 21, the FP trenches FT (including FP trenches FT1 to FT4) that are arranged in a dot shape and reach a middle of the drift region 21 from an upper surface 2a of the semiconductor layer, the insulating region 41 provided in the FP trench FT, and the FP electrode 13 provided in the insulating region 41 are formed.

An insulating region 61 and an insulating region 62 are formed on the upper surface 2a of the semiconductor layer. The insulating region 61 is a resist that covers the upper surface of FP electrode 13 and a part of the upper surface of the insulating region 41. The insulating region 62 is a resist that covers a part of the drift region 21 exposed on the upper surface 2a of the semiconductor layer. As illustrated in FIGS. 6, 7A, and 7B, an opening OP1 is formed between the insulating regions 61 adjacent to each other in the X-axis direction. The opening OP1 is also an opening formed between the insulating regions 62 adjacent to each other in the Y-axis direction. A part of the upper surface of the drift region 21 is exposed at the bottom of the opening OP1. Similarly, as illustrated in FIGS. 6 and 7C, an opening OP2 is formed between the insulating region 61 and the insulating region 62. A part of the upper surface of the drift region 21 and a part of the upper surface of the insulating region 41 are exposed at the bottom of the opening OP2.

Note that the semiconductor layers illustrated in FIGS. 6 and 7A to 7C are formed, for example, as follows. First, a semiconductor layer having the drift region 21 is prepared. Thereafter, an FP trench FT reaching the middle of the drift region 21 from the upper surface 2a of the semiconductor layer is formed by reactive ion etching (RIE) or the like. Thereafter, an insulating region covering an inner wall of the FP trench FT and the upper surface 2a of the semiconductor layer is formed by thermal oxidation or the like. Thereafter, a conductive material such as polysilicon is deposited on the upper surface 2a of the semiconductor layer by chemical vapor deposition (CVD) or the like. The conductive material fills the inside of the insulating region formed on the inner wall of the FP trench FT. Thereafter, a portion of the conductive material is removed by chemical mechanical polishing (CMP), chemical dry etching (CDE), or the like. As a result, the FP electrode 13 remains in the insulating region in the FP trench FT. Thereafter, a portion of the insulating region located above the upper surface 2a of the semiconductor layer is removed by RIE or the like. As a result, the insulating region 41 remains in the FP trench FT. Thereafter, an insulating material to be the insulating region 61 and the insulating region 62 is formed on the upper surface 2a of the semiconductor layer in a later step by CVD or the like. Thereafter, a resist is formed on the upper surface of the insulating material. Thereafter, the resist is exposed and developed to remove portions of the resist located above the opening OP1 and the opening OP2. Thereafter, portions of the insulating material corresponding to the opening OP1 and the opening OP2 are removed by RIE or the like. Thereafter, the remaining resist is removed. As a result, the insulating region 61 and the insulating region 62 are formed. The insulating region 61 and the insulating region 62 may be made of resist instead of the insulating material.

In the present embodiment, as illustrated in FIG. 7C, the outer periphery of the opening OP2 is slightly larger than the outer periphery of the insulating region 41. More specifically, a gap G exists between an end portion on the outer peripheral side of the opening OP2 and an end portion on the outer peripheral side of the insulating region 41. A part of the upper surface of the drift region 21 is exposed to the gap G. As a result, for example, when positional displacement of the opening OP2 occurs at the time of exposing and developing the resist, it is possible to suppress the thickness of the insulating region 42 from becoming non-uniform in a subsequent process.

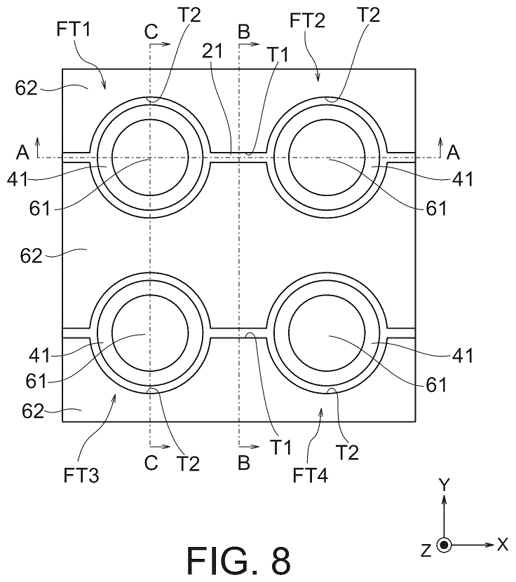

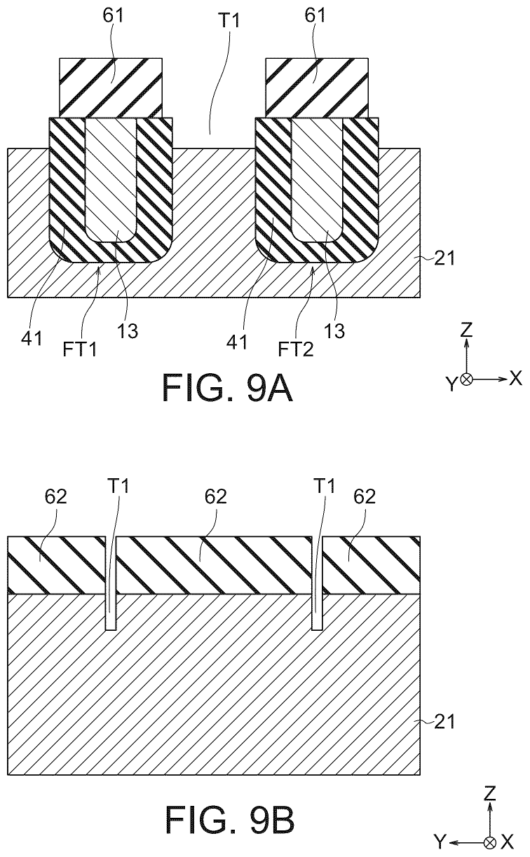

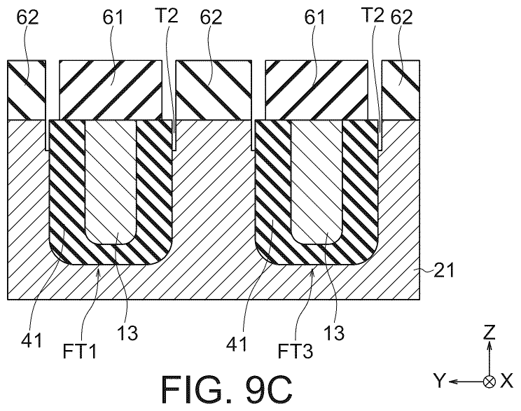

Next, as illustrated in FIGS. 8 and 9A to 9C, a part of the drift region 21 exposed in the opening OP1 and the opening OP2 is removed by RIE or the like using the insulating region 61 and the insulating region 62 as masks. As a result, a trench T1 and a trench T2 extending from the upper surface 2a of the semiconductor layer to the middle of the drift region 21 are formed.

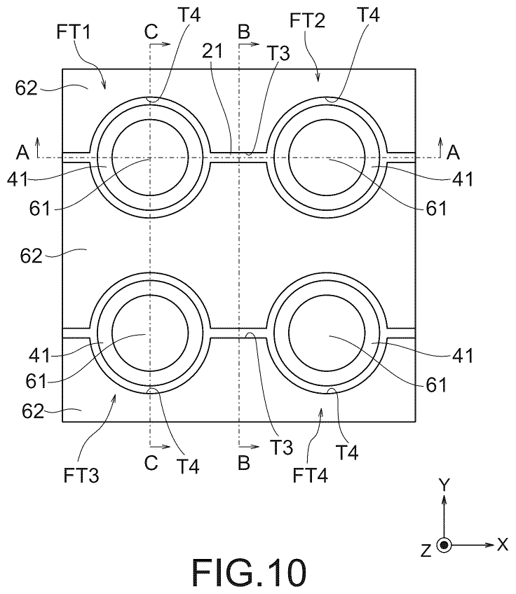

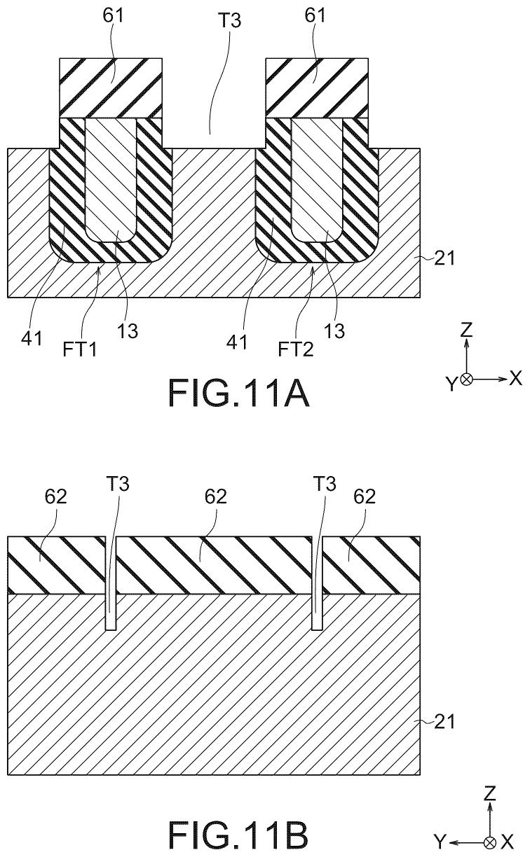

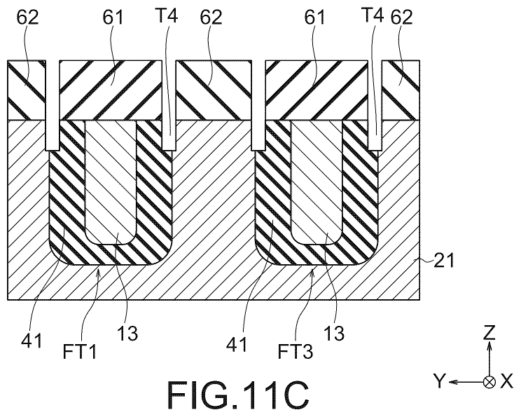

Next, as illustrated in FIGS. 10 and 11A to 11C, a part of the insulating region 41 exposed in the opening OP1 and the opening OP2 is removed by RIE or the like using the insulating region 61 and the insulating region 62 as masks. As a result, a part of the insulating region 41 located on the side of the trench T1 and the trench T2 is removed to form the trench T3 and the trench T4. Thereafter, the insulating region 61 and the insulating region 62 are removed.

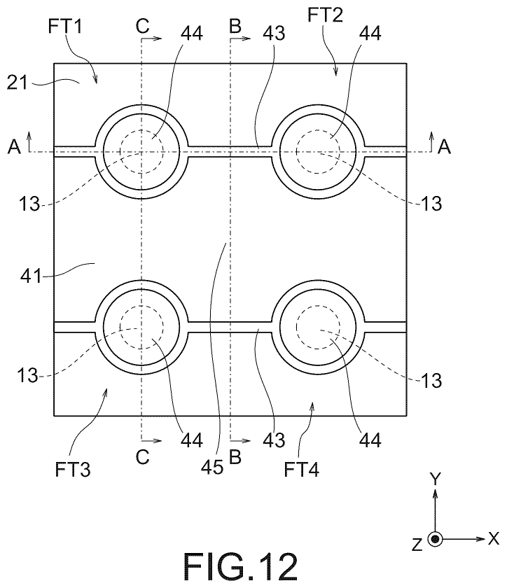

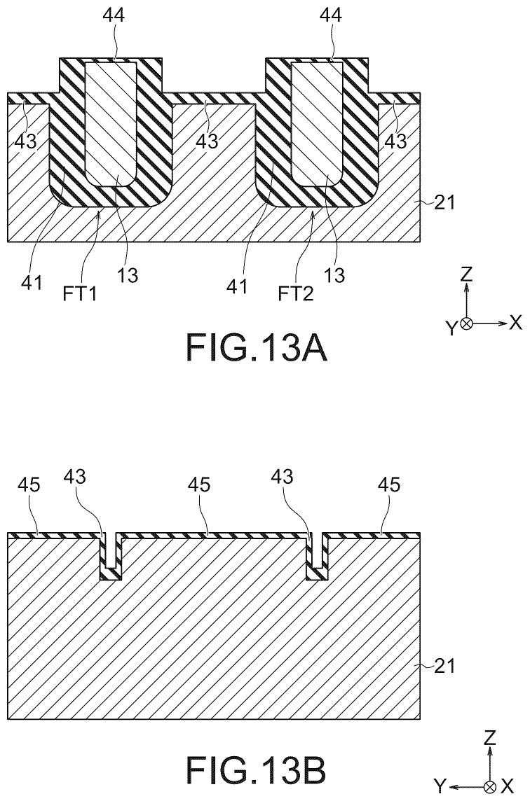

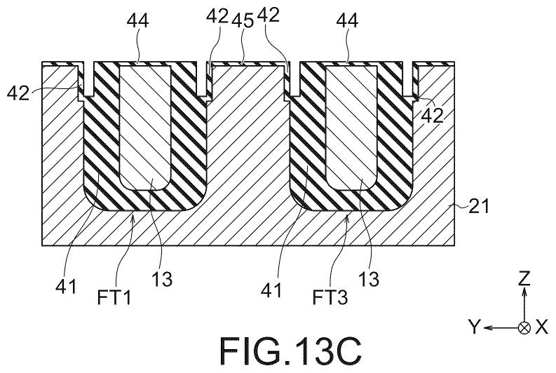

Next, as illustrated in FIGS. 12 and 13A to 13C, the insulating regions are formed in the trenches T3 and T4 and the upper surface of the FP electrode 13 by thermal oxidation or the like. As a result of this step, as illustrated in FIGS. 13A and 13B, the insulating region 43 is formed in the trench T3. As illustrated in FIG. 13C, the insulating region 42 is formed in the trench T4. As illustrated in FIGS. 13A and 13C, the insulating region 44 is formed on the FP electrode 13. As illustrated in FIGS. 13B and 13C, the insulating region 45 is formed on the drift region 21.

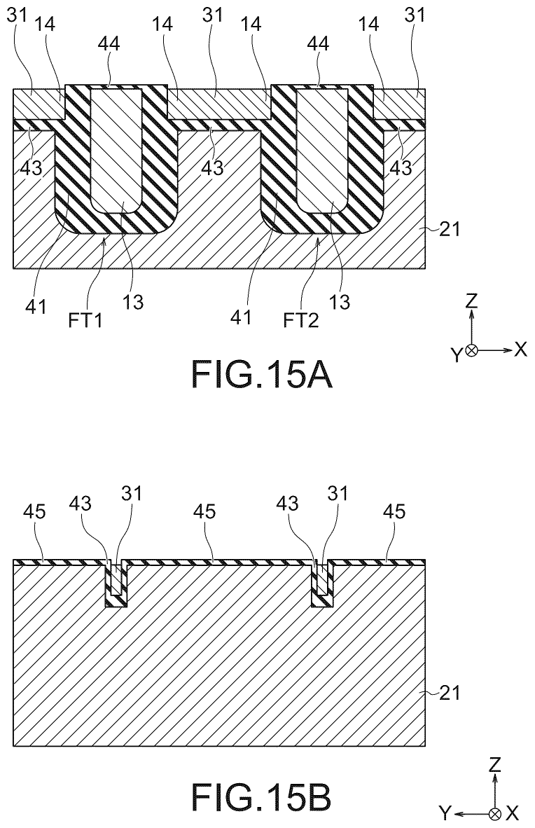

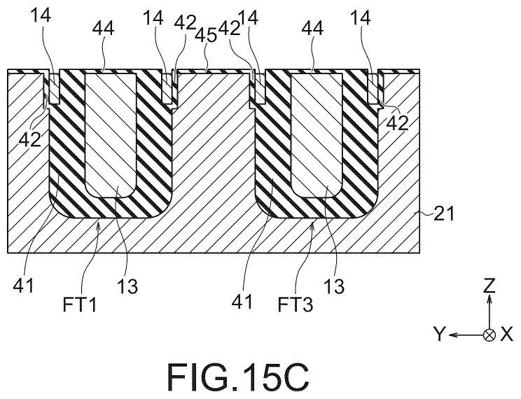

Next, as illustrated in FIGS. 14 and 15A to 15C, the gate electrode 14 and the conductive connection portion 31 are formed. More specifically, a conductive material such as polysilicon is deposited on the upper surface 2a of the semiconductor layer 2 by CVD or the like. Thereafter, a portion of the conductive material is removed by CMP, CDE, or the like. As a result, the gate electrode 14 remains in the insulating region 42, and the conductive connection portion 31 remains in the insulating region 43.

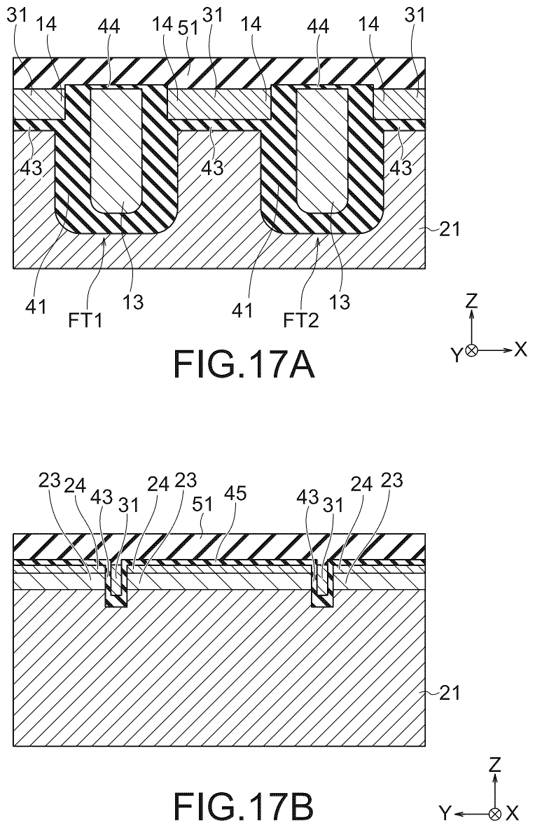

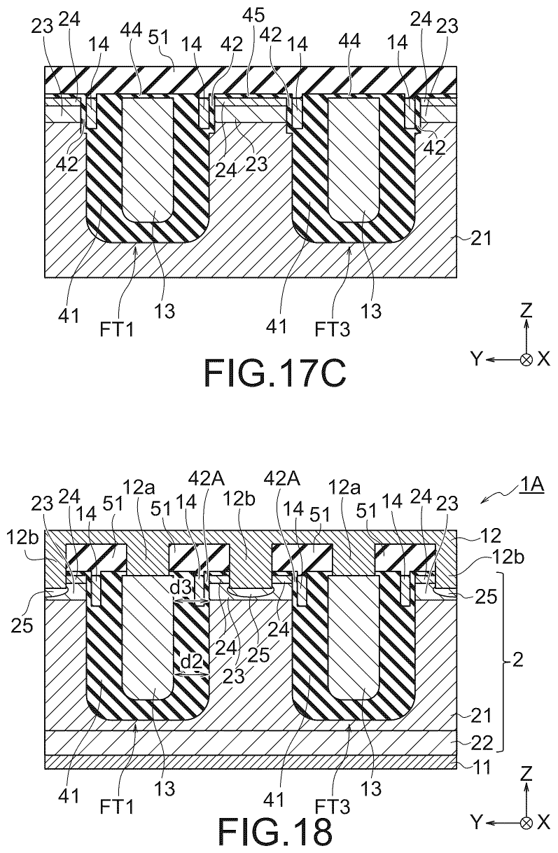

Next, as illustrated in FIGS. 16 and 17A to 17C, the p-type impurities are ion-implanted into the upper surface 2a of the semiconductor layer. Thereafter, the p-type impurities are diffused by heat treatment or the like to form the base region 23. Thereafter, the n-type impurities are ion-implanted into the upper surface 2a of the semiconductor layer. Thereafter, insulating materials such as a silicon oxide and the like are deposited on the upper surface 2a of the semiconductor layer by CVD or the like to form the insulating region 51. Thereafter, the n-type impurities are diffused by heat treatment or the like to form the source region 24. This makes it possible to omit the step of diffusing the n-type impurities before forming the insulating region 51. Before the insulating region 51 is formed, the source region 24 may be formed by diffusing n-type impurities.

Thereafter, although not illustrated, a first trench that penetrates the insulating region 51 and the insulating region 44 and reaches the upper surface of the FP electrode 13 and a second trench that penetrates the insulating region 51, the insulating region 45, and the source region 24 and reaches the middle of the base region 23 are formed by RIE or the like. Thereafter, the p-type impurities are ion-implanted into the upper surface of the semiconductor layer, and heat treatment or the like is performed to form the high-concentration region 25 at the bottom of the second trench.

Thereafter, the n-type impurities are ion-implanted into the lower surface of the semiconductor layer, and heat treatment or the like is performed to form the drain region 22. Thereafter, the drain electrode 11 is formed on the lower surface of the semiconductor layer, and the source electrode 12 is formed on the upper surface 2a of the semiconductor layer. Here, the source electrode 12 includes a contact portion 12a and a contact portion 12b. In addition, the contact portion 12a fills the above-described first trench, and the contact portion 12b fills the above-described second trench. Thereafter, in a termination region of the semiconductor layer 2 or the like, a passivation film containing polyimide or the like for electrically insulating the source electrode 12 from the gate wiring layer or the like may be formed. Through the above process, the semiconductor device 1 is manufactured.

### Modification of First Embodiment

FIG. 18 is a diagram corresponding to a cross-sectional view taken along line C-C in FIG. 2 in a semiconductor device 1A according to Modification of the first embodiment. As illustrated in FIG. 18, the semiconductor device 1A according to the present modification corresponds to a case where the side surface on the outer peripheral side of the insulating region 42A is flush with the side surface on the outer peripheral side of the insulating region 41 in the semiconductor device 1 according to the first embodiment. The insulating region 42A corresponds to the insulating region 42 in the first embodiment.

More specifically, as illustrated in FIG. 18, for at least one FP trench FT (for example, FP trench FT1), a third distance d3 in the X-axis direction between the FP electrode 13 and the semiconductor layer 2 at a height at which the gate electrode 14 is provided is equal to a second distance d2 in the X-axis direction between the FP electrode 13 and the semiconductor layer 2 at a height at which the gate electrode 14 is not provided.

According to the present modification, similar to the first embodiment, in the semiconductor device 1 including the plurality of FP electrodes 13 arranged in a dot shape, it is possible to simplify the wiring structure between the gate electrodes 14 while reducing the gate-drain capacitance.

The present modification may be combined with the first embodiment described above. That is, in the semiconductor device, the insulating region 42A whose side surface on the outer peripheral side is flush with the insulating region 41 may be provided in at least one FP trench FT, and the insulating region 42 whose side surface on the outer peripheral side is farther from the center of the FP electrode 13 than the side surface on the outer peripheral side of the insulating region 41 may be provided in at least one FP trench FT among the remaining FP trenches FT.

Furthermore, the semiconductor device 1A according to the present modification can be manufactured, for example, by providing the opening OP2 such that the end portion on the outer peripheral side of the opening OP2 coincides with the end portion on the outer peripheral side of the insulating region 41 in the above-described steps illustrated in FIGS. 6 and 7A to 7C.

### Second Embodiment

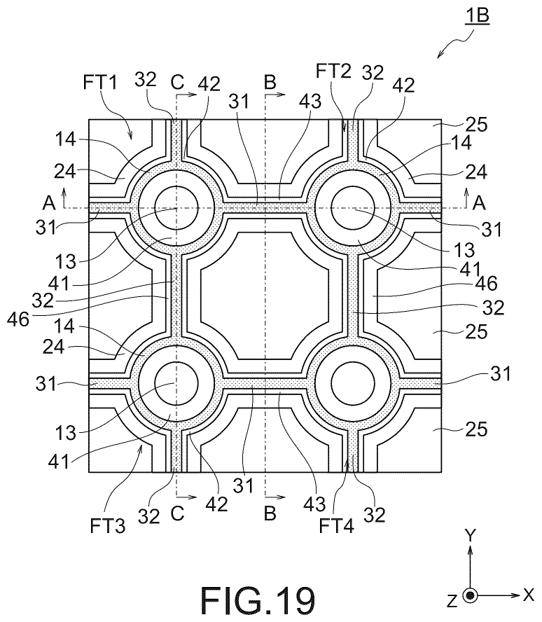

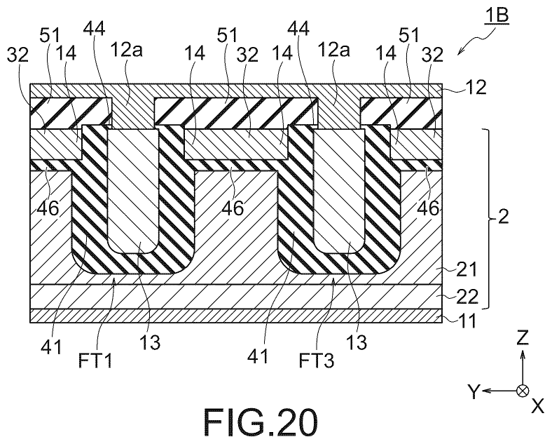

FIG. 19 is a plan view of a semiconductor device 1B according to the second embodiment, and is an enlarged view of a region corresponding to the region R in FIG. 1 in the first embodiment. FIG. 20 is a cross-sectional view of the semiconductor device 1B according to the second embodiment, taken along line C-C in FIG. 19. The semiconductor device 1B according to the present embodiment is obtained by adding a conductive connection portion 32 that connects the gate electrodes 14 adjacent to each other in the Y-axis direction in the semiconductor device 1 according to the first embodiment. Hereinafter, the present embodiment will be described focusing on the differences from the first embodiment described above. Note that, regarding the semiconductor device 1B according to the present embodiment, the cross-sectional view taken along line A-A of FIG. 19 is similar to FIG. 3. A cross-sectional view taken along line B-B in FIG. 19 is similar to FIG. 4.

As illustrated in FIG. 19, in the semiconductor layer 2 of the present embodiment, a conductive connection portion 32 and an insulating region 46 are provided in addition to each part in the semiconductor layer 2 of the first embodiment.

The conductive connection portion 32 electrically connects each gate electrode 14 of the plurality of gate electrodes 14 surrounding each of the plurality of FP electrodes 13 of the first FP electrode group and each gate electrode 14 of the plurality of gate electrodes 14 surrounding each of the plurality of FP electrodes 13 of the second FP electrode group adjacent to the FP electrodes 13 in the Y-axis direction. In the example of FIG. 19, the conductive connection portion 32 located between the FP trench FT1 and the FP trench FT3 electrically connects the gate electrode 14 of the FP trench FT1 and the gate electrode 14 of the FP trench FT3. In addition, the conductive connection portion 32 located between the FP trench FT2 and the FP trench FT4 electrically connects the gate electrode 14 of the FP trench FT2 and the gate electrode 14 of the FP trench FT4. As another example, in FIG. 19, the conductive connection portion 32 located on the upper side of the FP trench FT1 electrically connects the gate electrode 14 of the FP trench FT1 and the gate electrode 14 of the FP trench FT located on the upper side of the FP trench FT1. The conductive connection portion 32 is an example of the third conductive connection portion in the claims.

Note that at least one conductive connection portion 32 may be provided in the semiconductor device 1B. For example, one of the conductive connection portion 32 located between the FP trench FT1 and the FP trench FT3 and the conductive connection portion 32 located between the FP trench FT2 and the FP trench FT4 may be omitted. Further, as long as each gate electrode 14 is electrically connected to a gate pad or the like, some of the conductive connection portions 31 may be omitted. For example, one of the conductive connection portion 31 located between the FP trench FT1 and the FP trench FT2 and the conductive connection portion 31 located between the FP trench FT3 and the FP trench FT4 may be omitted.

As illustrated in FIG. 20, the details of the longitudinal section of the conductive connection portion 32 are similar to those of the conductive connection portion 31. More specifically, the conductive connection portion 32 is provided in the semiconductor layer 2 via the insulating region 46. That is, the conductive connection portion 32 faces the base region 23 via the insulating region 46. In the present embodiment, the upper end of at least one conductive connection portion 32 of the plurality of conductive connection portions 32 is located in the source region 24, and the lower end of the at least one conductive connection portion 32 is located in the drift region 21. In the present embodiment, the upper ends of the plurality of conductive connection portions 32 are located at the same height in the Z-axis direction as the upper ends of the gate electrodes 14, and the lower ends of the plurality of conductive connection portions 32 are located at the same height in the Z-axis direction as the lower ends of the gate electrodes 14.

In the plane illustrated in FIG. 19, the insulating region 46 is provided between the conductive connection portion 32 and the source region 24. The insulating region 46 connects the insulating regions 41 provided in the FP trenches FT adjacent to each other in the Y-axis direction. For example, the insulating region 44 connects the insulating region 41 in the FP trench FT1 and the insulating region 41 in the FP trench FT3. Further, the insulating region 44 connects the insulating region 41 in the FP trench FT2 and the insulating region 41 in the FP trench FT4. The insulating region 46 is an example of a fifth insulating region in the claims.

As illustrated in FIG. 20, the details of the longitudinal cross section of the insulating region 46 are similar to those of the insulating region 43. More specifically, the insulating region 46 electrically insulates the conductive connection portion 32 from the semiconductor layer 2. The insulating region 46 is provided on the inner wall of the trench in which the conductive connection portion 32 is provided. Note that the insulating region 46 contains, for example, a silicon oxide or a silicon nitride.

According to the present embodiment, in addition to the channel region of the first embodiment, the channel region is also formed in the base region 23 facing the conductive connection portion 32. As a result, the on-resistance of the semiconductor device 1B can be further reduced.

### Third Embodiment

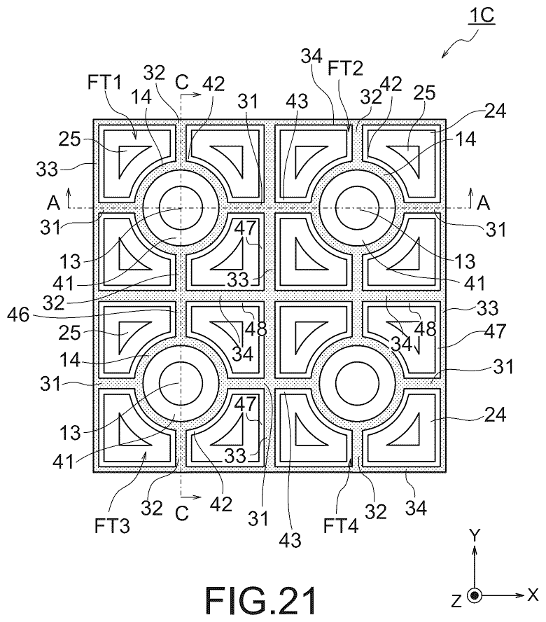

FIG. 21 is a plan view of a semiconductor device 1C according to the third embodiment, and is an enlarged view of a region corresponding to the region R in FIG. 1 in the first embodiment. A semiconductor device 1C according to the present embodiment is obtained by adding a conductive connection portion 33 electrically connecting the conductive connection portions 31 adjacent to each other in the Y-axis direction and a conductive connection portion 34 electrically connecting the conductive connection portions 32 adjacent to each other in the X-axis direction in the semiconductor device 1B according to the second embodiment. Hereinafter, the present embodiment will be described focusing on the differences from the second embodiment described above. Note that, regarding the semiconductor device 1C according to the present embodiment, the cross-sectional view taken along line A-A of FIG. 21 is similar to FIG. 3. A cross-sectional view taken along line C-C in FIG. 21 is similar to that in FIG. 20.

As illustrated in FIG. 21, in the semiconductor layer 2 of the present embodiment, the conductive connection portion 33, the conductive connection portion 34, an insulating region 47, and an insulating region 48 are provided in addition to each portion in the semiconductor layer 2 of the second embodiment.

The conductive connection portion 33 is provided between the FP electrodes 13 adjacent to each other in the X-axis direction, and extends in the Y-axis direction. In other words, the conductive connection portion 33 electrically connects the conductive connection portions 31 adjacent to each other in the Y-axis direction. For example, the conductive connection portion 33 electrically connects each conductive connection portion 31 of the plurality of conductive connection portions 31 (first conductive connection portions) electrically connecting the gate electrode 14 of the FP trench FT1 and the gate electrode 14 of the FP trench FT2 and each conductive connection portion 31 of the plurality of conductive connection portions 31 (second conductive connection portions) electrically connecting the gate electrode 14 of the FP trench FT3 and the gate electrode 14 of the FP trench FT4. That is, the conductive connection portion 33 electrically connects each of the first conductive connection portions and each of the second conductive connection portions. Here, the first conductive connection portions and the second conductive connection portions are adjacent to each other in the Y-axis direction. The conductive connection portion 33 is an example of the fourth conductive connection portion in the claims.

The conductive connection portion 34 is provided between the FP electrodes 13 adjacent to each other in the Y-axis direction, and extends in the X-axis direction. In other words, the conductive connection portion 34 electrically connects the conductive connection portions 32 adjacent to each other in the X-axis direction. For example, the conductive connection portion 34 electrically connects the conductive connection portions 32 (third conductive connection portions) electrically connecting the gate electrode 14 of the FP trench FT1 and the gate electrode 14 of the FP trench FT3 and the conductive connection portions 32 (third conductive connection portions) electrically connecting the gate electrode 14 of the FP trench FT2 and the gate electrode 14 of the FP trench FT4. That is, the conductive connection portion 34 electrically connects each of the plurality of third conductive connection portions adjacent to each other in the X-axis direction. The conductive connection portion 34 is an example of the fifth conductive connection portion in the claims.

The details of longitudinal sections of the conductive connection portion 33 and the conductive connection portion 34 are similar to those of the conductive connection portion 31. More specifically, the conductive connection portion 33 is provided in the semiconductor layer 2 via the insulating region 47. The conductive connection portion 34 is provided in the semiconductor layer 2 via the insulating region 48. In the present embodiment, the upper end of at least one conductive connection portion 33 of the plurality of conductive connection portions 33 is located in the source region 24, and the lower end of the at least one conductive connection portion 32 is located in the drift region 21. In the present embodiment, the upper end of at least one conductive connection portion 34 of the plurality of conductive connection portions 34 is located in the source region 24, and the lower end of the at least one conductive connection portion 34 is located in the drift region 21. In the present embodiment, the upper ends of the plurality of conductive connection portions 33 are located at the same height in the Z-axis direction as the upper ends of the gate electrodes 14, and the lower ends of the plurality of conductive connection portions 33 are located at the same height in the Z-axis direction as the lower ends of the gate electrodes 14. In the present embodiment, the upper ends of the plurality of conductive connection portions 34 are located at the same height in the Z-axis direction as the upper ends of the gate electrodes 14, and the lower ends of the plurality of conductive connection portions 34 are located at the same height in the Z-axis direction as the lower ends of the gate electrodes 14.

In the plane illustrated in FIG. 21, the insulating region 47 is provided between the conductive connection portion 33 and the source region 24. The insulating region 47 connects the insulating regions 43 adjacent to each other in the Y-axis direction. For example, the insulating region 47 connects the insulating region 43 connecting the insulating region 41 in the FP trench FT1 and the insulating region 41 in the FP trench FT2 and the insulating region 43 connecting the insulating region 41 in the FP trench FT3 and the insulating region 41 in the FP trench FT4. The insulating region 47 is an example of a sixth insulating region in the claims.

Similarly, in the plane illustrated in FIG. 21, the insulating region 48 is provided between the conductive connection portion 34 and the source region 24. The insulating region 48 connects the insulating regions 46 adjacent to each other in the X-axis direction. For example, the insulating region 48 connects the insulating region 46 connecting the insulating region 41 in the FP trench FT1 and the insulating region 41 in the FP trench FT3 and the insulating region 46 connecting the insulating region 41 in the FP trench FT2 and the insulating region 41 in the FP trench FT4. The insulating region 48 is an example of a seventh insulating region in the claims.

The details of the longitudinal sections of the insulating region 47 and the insulating region 48 are similar to those of the insulating region 43. More specifically, the insulating region 47 electrically insulates the conductive connection portion 33 from the semiconductor layer 2. Further, the insulating region 48 electrically insulates the conductive connection portion 34 from the semiconductor layer 2. The insulating region 47 is provided on the inner wall of the trench in which the conductive connection portion 33 is provided. The insulating region 48 is provided on the inner wall of the trench in which the conductive connection portion 34 is provided. Note that the insulating region 47 contains, for example, a silicon oxide or a silicon nitride. Note that the insulating region 48 contains, for example, a silicon oxide or a silicon nitride.

According to the present embodiment, since the conductive connection portion 33 and the conductive connection portion 34 are provided, more channel regions are formed than in the second embodiment. Therefore, the on-resistance of the semiconductor device 1C can be further reduced.

In the above example, the case where both the conductive connection portion 33 and the conductive connection portion 34 are provided has been described. Not limited to this, one of the conductive connection portion 33 and the conductive connection portion 34 may be provided, and the other may not be provided. When both the conductive connection portion 33 and the conductive connection portion 34 are provided, at least one of the conductive connection portion 33 and the conductive connection portion 34 may be provided in the semiconductor device 1C. A plurality of conductive connection portions 33 extending in the Y-axis direction may be provided between the FP electrodes 13 adjacent to each other in the X-axis direction. Similarly, a plurality of the conductive connection portions 34 extending in the X-axis direction may be provided between the FP electrodes 13 adjacent to each other in the Y-axis direction.

### Fourth Embodiment

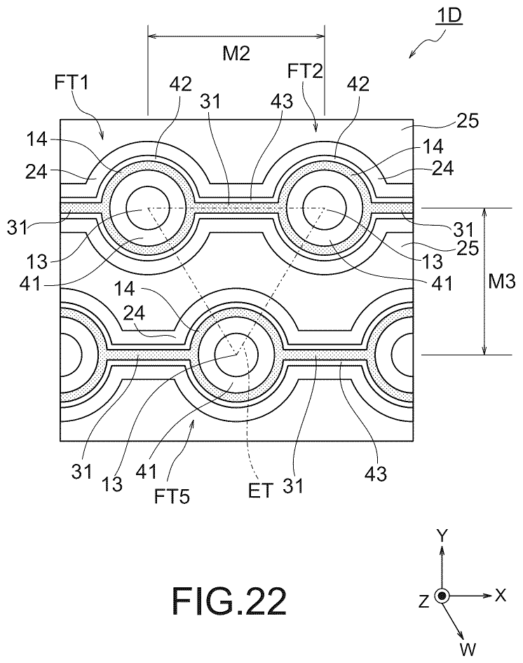

FIG. 22 is a plan view of a semiconductor device 1D according to the fourth embodiment, and is an enlarged view of a region corresponding to the region R in FIG. 1 in the first embodiment. The semiconductor device 1D according to the present embodiment is the semiconductor device 1 according to the first embodiment in which the FP electrodes 13 are arranged in a triangular shape. Hereinafter, the present embodiment will be described focusing on the differences from the first embodiment described above. In the present embodiment, the FP electrodes 13 in the FP trench FT5 and the other FP electrodes 13 aligned with the FP electrodes 13 in the X-axis direction are collectively referred to as a second FP electrode group.

As illustrated in FIG. 22, in the semiconductor device 1D according to the present embodiment, the FP electrodes 13 included in the FP electrode groups adjacent in the Y-axis direction are arranged to be shifted in the X-axis direction. For example, the FP electrodes 13 of the first FP electrode group are different in a position (X-coordinate) in the X-axis direction from the FP electrodes 13 of the second FP electrode group. In other words, the FP electrodes 13 of the first FP electrode group and the FP electrodes 13 of the second FP electrode group are arranged along a W-axis direction orthogonal to the Z-axis direction and oblique to the X-axis direction and the Y-axis direction. For example, the FP electrode 13 in the FP trench FT1 and the FP electrode 13 in the FP trench FT5 are arranged along the W-axis direction. The W-axis direction is an example of the fourth direction in the claims.

In addition, a distance between the center of each FP electrode 13 of the first FP electrode group and the center of each FP electrode 13 of the second FP electrode group in the Y-axis direction is a distance M3. Here, the distance M3 is shorter than the distance M2 between the centers of the plurality of FP electrodes 13 of the first FP electrode group. Note that the distance M3 may be the same as the distance M2 or may be longer than the distance M2.

In the present embodiment, the FP electrodes 13 provided in the semiconductor device 1 are arranged in an equilateral triangle shape For example, as illustrated in FIG. 22, the centers of the FP electrodes 13 in the FP trenches FT1, FT2, and FT5 are located at three vertexes of an equilateral triangle ET in the XY plane. The angle formed between the X-axis direction and the W-axis direction is, for example, 60 degrees in the XY plane.

According to the present embodiment, the distance M3 between the FP electrode groups adjacent to each other in the Y-axis direction can be made shorter than the distance M2 between the FP electrodes 13 adjacent to each other in each FP electrode group. Therefore, the density of the FP electrodes 13 in the semiconductor device 1D can be increased. Therefore, the withstand voltage of the semiconductor device 1D can be further improved. In addition, since the density of the conductive connection portions 31 also increases with the increase in the density of the FP electrodes 13, the ratio of the channel region increases, and the on-resistance of the semiconductor device 1C can be further reduced.

In the present embodiment, for example, at least one conductive connection portion extending in the W-axis direction for electrically connecting the gate electrode 14 of the FP trench FT1 and the gate electrode 14 of the FP trench FT5 may be provided. Alternatively, for example, at least one conductive connection portion extending in the Y-axis direction for electrically connecting the conductive connection portion 31 between the FP trench FT1 and the FP trench FT2 and the gate electrode 14 of the FP trench FT5 may be provided.

The first to fourth embodiments have been described above. In each embodiment, the planar shape of FP electrode 13 and the planar shape of gate electrode 14 surrounding FP electrode 13 were circular. The planar shape of at least one of FP electrode 13 and gate electrode 14 is not limited to this, and may be a polygon such as a quadrangle, a rectangle, a square, a hexagon, or a regular hexagon. For example, in the first to third embodiments, the planar shapes of FP electrode 13 and gate electrode 14 may be square, and in the fourth embodiment, the planar shapes of FP electrode 13 and gate electrode 14 may be regular hexagons.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

1. A semiconductor device comprising:
a first electrode;
a second electrode;
a semiconductor layer provided between the first electrode and the second electrode, the semiconductor layer including
a first semiconductor region of a first conductivity type electrically connected to the first electrode;
a second semiconductor region of a second conductivity type located above the first semiconductor region; and
a third semiconductor region of a first conductivity type located above the second semiconductor region;
a first field plate electrode group provided in the first semiconductor region via a first insulating region and including a plurality of field plate electrodes arranged in a second direction orthogonal to a first direction from the first electrode toward the second electrode;
a second field plate electrode group that is provided in the first semiconductor region via a second insulating region, including a plurality of field plate electrodes arranged in the second direction, and being adjacent to the first field plate electrode group in a third direction orthogonal to the first direction and the second direction;
a plurality of gate electrodes provided in the first insulating region and the second insulating region so as to surround each field plate electrode of the plurality of field plate electrodes of the first field plate electrode group and the plurality of field plate electrodes of the second field plate electrode group, and the plurality of gate electrodes facing the second semiconductor region;
a plurality of first conductive connection portions provided in the semiconductor layer via a third insulating region and electrically connecting the plurality of gate electrodes surrounding each of the plurality of field plate electrodes of the first field plate electrode group; and
a plurality of second conductive connection portions provided in the semiconductor layer via a fourth insulating region and electrically connecting the plurality of gate electrodes surrounding each of the plurality of field plate electrodes of the second field plate electrode group.

2. The semiconductor device according to claim 1, wherein at least one first conductive connection portion of the plurality of first conductive connection portions faces the second semiconductor region via the third insulating region.

3. The semiconductor device according to claim 2, wherein each of the plurality of field plate electrodes of the first field plate electrode group and each of the plurality of field plate electrodes of the second field plate electrode group are arranged along the third direction.

4. The semiconductor device according to claim 2, wherein each of the plurality of field plate electrodes of the first field plate electrode group and each of the plurality of field plate electrodes of the second field plate electrode group are arranged along a fourth direction orthogonal to the first direction and oblique to the second direction and the third direction.

5. The semiconductor device according to claim 2, wherein a first distance between at least one field plate electrode of the plurality of field plate electrodes of the first field plate electrode group and the plurality of field plate electrodes of the second field plate electrode group and the semiconductor layer at a first height is longer than a second distance between the at least one field plate electrode and the semiconductor layer at a second height,
wherein the first height is a height at which the gate electrode surrounding the at least one field plate electrode is provided, and the second height is a height at which the gate electrode is not provided.

6. The semiconductor device according to claim 2, wherein an upper end of at least one first conductive connection portion among the plurality of first conductive connection portions is located in the third semiconductor region in the first direction, and
a lower end of the at least one first conductive connection portion is located in the first semiconductor region in the first direction.

7. The semiconductor device according to claim 6, wherein each of the plurality of field plate electrodes of the first field plate electrode group and each of the plurality of field plate electrodes of the second field plate electrode group are arranged along the third direction.

8. The semiconductor device according to claim 6, wherein each of the plurality of field plate electrodes of the first field plate electrode group and each of the plurality of field plate electrodes of the second field plate electrode group are arranged along a fourth direction orthogonal to the first direction and oblique to the second direction and the third direction.

9. The semiconductor device according to claim 6, wherein a first distance between at least one field plate electrode of the plurality of field plate electrodes of the first field plate electrode group and the plurality of field plate electrodes of the second field plate electrode group and the semiconductor layer at a first height is longer than a second distance between the at least one field plate electrode and the semiconductor layer at a second height,
wherein the first height is a height at which the gate electrode surrounding the at least one field plate electrode is provided, and the second height is a height at which the gate electrode is not provided.

10. The semiconductor device according to claim 2, wherein upper ends of the plurality of first conductive connection portions are located at the same height in the first direction as upper ends of the plurality of gate electrodes surrounding each of the plurality of field plate electrodes of the first field plate electrode group, and
lower ends of the plurality of first conductive connection portions are located at the same height in the first direction as lower ends of the plurality of gate electrodes surrounding each of the plurality of field plate electrodes.

11. The semiconductor device according to claim 10, wherein each of the plurality of field plate electrodes of the first field plate electrode group and each of the plurality of field plate electrodes of the second field plate electrode group are arranged along the third direction.

12. The semiconductor device according to claim 10, wherein each of the plurality of field plate electrodes of the first field plate electrode group and each of the plurality of field plate electrodes of the second field plate electrode group are arranged along a fourth direction orthogonal to the first direction and oblique to the second direction and the third direction.

13. The semiconductor device according to claim 10, wherein a first distance between at least one field plate electrode of the plurality of field plate electrodes of the first field plate electrode group and the plurality of field plate electrodes of the second field plate electrode group and the semiconductor layer at a first height is longer than a second distance between the at least one field plate electrode and the semiconductor layer at a second height,
wherein the first height is a height at which the gate electrode surrounding the at least one field plate electrode is provided, and the second height is a height at which the gate electrode is not provided.

14. The semiconductor device according to claim 1, wherein each of the plurality of field plate electrodes of the first field plate electrode group and each of the plurality of field plate electrodes of the second field plate electrode group are arranged along the third direction.

15. The semiconductor device according to claim 14, further comprising: a plurality of third conductive connection portions provided in the semiconductor layer via a fifth insulating region, wherein each third conductive connection portion of the plurality of third conductive connection portions electrically connect each gate electrode of the plurality of gate electrodes surrounding each of the plurality of field plate electrodes of the first field plate electrode group and each gate electrode of the plurality of gate electrodes surrounding each of the plurality of field plate electrodes of the second field plate electrode group.

16. The semiconductor device according to claim 15, further comprising: a plurality of fourth conductive connection portions provided in the semiconductor layer via a sixth insulating region, wherein each forth conductive connection portion of the plurality of fourth conductive connection portions electrically connect each first conductive connection portion of the plurality of first conductive connection portions and each second conductive connection portion of the plurality of second conductive connection portions.

17. The semiconductor device according to claim 15, further comprising: a plurality of fifth conductive connection portions provided in the semiconductor layer via a seventh insulating region, wherein each fifth conductive connection portion of the plurality of fifth conductive connection portions electrically connect third conductive connection portions adjacent to each other in the second direction among the plurality of third conductive connection portions.

18. The semiconductor device according to claim 1, wherein each of the plurality of field plate electrodes of the first field plate electrode group and each of the plurality of field plate electrodes of the second field plate electrode group are arranged along a fourth direction orthogonal to the first direction and oblique to the second direction and the third direction.

19. The semiconductor device according to claim 18, wherein a distance between a center of each of the field plate electrodes of the first field plate electrode group and a center of each of the field plate electrodes of the second field plate electrode group in the third direction is shorter than a distance between centers of the plurality of field plate electrodes of the first field plate electrode group.

20. The semiconductor device according to claim 1, wherein a first distance between at least one field plate electrode of the plurality of field plate electrodes of the first field plate electrode group and the plurality of field plate electrodes of the second field plate electrode group and the semiconductor layer at a first height is longer than a second distance between the at least one field plate electrode and the semiconductor layer at a second height,
wherein the first height is a height at which the gate electrode surrounding the at least one field plate electrode is provided, and the second height is a height at which the gate electrode is not provided.
